(19) United States
(12) Patent Application Publication
(10) Pub. No.: US 2025/0191930 A1
(43) Pub. Date: Jun. 12, 2025

(54) DEEP ULTRAVIOLET LITHOGRAPHY METHOD, LITHOGRAPHY PATTERN AND SEMICONDUCTOR STRUCTURE

(71) Applicant: INSTITUTE OF MICROELECTRONICS, CHINESE ACADEMY OF SCIENCES, Beijing (CN)

(72) Inventors: Xiaobin He, Beijing (CN); Junfeng Li, Beijing (CN); Tingting Li, Beijing (CN); Jinbiao Liu, Beijing (CN); Jianfeng Gao, Beijing (CN); Tao Yang, Beijing (CN); Jun Luo, Beijing (CN)

(21) Appl. No.: 18/936,725

(22) Filed: Nov. 4, 2024

(30) Foreign Application Priority Data
Dec. 11, 2023 (CN) 202311697079.3

(51) Int. Cl. H01L 21/311; G03F 7/20

(52) U.S. Cl. CPC H01L 21/31144; G03F 7/2004

(57) ABSTRACT

The present disclosure discloses a deep ultraviolet lithography method, a lithography pattern and a semiconductor structure, which relates to the field of deep ultraviolet lithography technology. The deep ultraviolet lithography method includes: dividing, when a depth of field of the deep ultraviolet lithography is less than a height of the step of the substrate, a pattern to be photoetched into at least two portions according to a distribution situation of the step, where each of the at least two portions corresponds to an on-step pattern or an off-step pattern of the step; corresponding the at least two portions of the pattern to be photoetched onto at least two masks respectively; and simultaneously baking and developing the exposed at least two masks after the at least two masks are exposed sequentially.

### CROSS REFERENCE TO RELATED APPLICATION

This application claims priority to Chinese Patent Application No. 202311697079.3, filed on Dec. 11, 2023, the entire content of which is incorporated herein in its entirety by reference.

### TECHNICAL FIELD

The present disclosure relates to the field of deep ultraviolet lithography technology, in particular to a deep ultraviolet lithography method, a lithography pattern and a semiconductor structure.

### BACKGROUND

Deep ultraviolet lithography technology is a high-accuracy and high-efficiency microelectronic manufacturing technology, which is an important means to apply the lithography technology to the field of microelectronic manufacturing. The main principle of the deep ultraviolet lithography technology is to expose a photoresist by using a deep ultraviolet light source, and then transfer a pattern of the photoresist onto a silicon wafer through a chemical reaction, thereby achieving manufacturing of microelectronic devices.

The advantages of the deep ultraviolet lithography technology lie in its high resolution, high accuracy and high efficiency. Since a wavelength of deep ultraviolet light is short, a higher resolution and a smaller feature size may be achieved. Meanwhile, the deep ultraviolet lithography technology may also achieve high-accuracy alignment and multi-layer pattern manufacturing, thereby greatly improving the manufacturing efficiency and quality of microelectronic devices.

However, a focused depth of field of the deep ultraviolet lithography process is generally small. When a substrate has a relatively high step, the exposure may not be performed normally by using the deep ultraviolet lithography process.

### SUMMARY

In a first aspect, the present disclosure discloses a deep ultraviolet lithography method, applied in a substrate having a step, including:
dividing, when a depth of field of the deep ultraviolet lithography is less than a height of the step of the substrate, a pattern to be photoetched into at least two portions according to a distribution situation of the step, where each of the at least two portions corresponds to an on-step pattern or an off-step pattern of the step;
corresponding the at least two portions of the pattern to be photoetched onto at least two masks respectively; and
simultaneously baking and developing the exposed at least two masks after the at least two masks are exposed sequentially.

Furthermore, the deep ultraviolet lithography method further includes:
coating an antireflection layer on the substrate by using a glue spraying method.

Furthermore, a thickness of the antireflection layer is less than 60 nm.

Furthermore, when the depth of field of the deep ultraviolet lithography is less than the height of the step of the substrate and the pattern to be photoetched includes a step pattern corresponding to one step, the step pattern corresponding to the step is divided into the on-step pattern and the off-step pattern.

Furthermore, the corresponding the at least two portions of the pattern to be photoetched onto at least two masks respectively includes:
corresponding the on-step pattern onto a first mask, and corresponding the off-step pattern onto a second mask.

Furthermore, the simultaneously baking and developing the exposed at least two masks after the at least two masks are exposed sequentially includes:
exposing the first mask first, and then exposing the second mask; and
simultaneously baking and developing the exposed first mask and the exposed second mask.

Furthermore, the height of the step in the substrate is greater than or equal to 500 nm.

In a second aspect, the present disclosure provides a lithography pattern. The lithography pattern is prepared by the deep ultraviolet lithography method.

In a third aspect, the present disclosure further provides a semiconductor structure. The semiconductor structure includes a substrate prepared by using the lithography pattern.

### BRIEF DESCRIPTION OF THE DRAWINGS

The accompanying drawing illustrated here is used to provide a further understanding of the present disclosure and constitutes a part of the present disclosure. The illustrative embodiments of the present disclosure and the descriptions thereof are used to explain the present disclosure and do not constitute an improper limitation of the present disclosure. In the accompanying drawing:

FIG. 1 shows steps of a deep ultraviolet lithography method provided by the embodiments of the present disclosure.

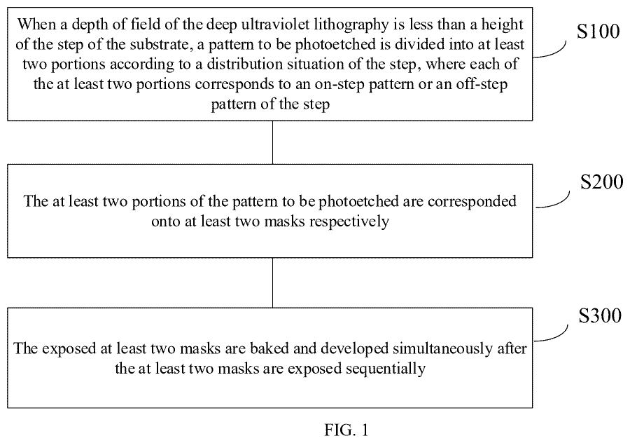

### DETAILED DESCRIPTION OF EMBODIMENTS

Hereinafter, the embodiments of the present disclosure will be described with reference to the accompanying drawing. However, it should be understood that these descriptions are only exemplary and are not intended to limit the scope of the present disclosure. Additionally, in the following description, descriptions of well-known structures and technologies are omitted to avoid unnecessarily confusing the concept of the present disclosure.

In addition, the terms “first” and “second” are only used for descriptive purposes, and may not be understood as indicating or implying relative importance or implicitly showing the number of the indicated technical features. Therefore, the features defined with “first” and “second” may include one or more of the features explicitly or implicitly. In the description of the present disclosure, the term “plurality” means two or more, unless otherwise specifically defined. The term “several” means one or more, unless otherwise specifically defined.

Deep ultraviolet lithography technology is a high-accuracy and high-efficiency microelectronic manufacturing technology, which is an important means to apply the lithography technology to the field of microelectronic manufacturing. The main principle of the deep ultraviolet lithography technology is to expose a photoresist by using a deep ultraviolet light source, and then transfer a pattern of the photoresist onto a silicon wafer through a chemical reaction, thereby achieving manufacturing of microelectronic devices.

The advantages of the deep ultraviolet lithography technology lie in its high resolution, high accuracy and high efficiency. Since a wavelength of deep ultraviolet light is short, a higher resolution and a smaller feature size may be achieved. Meanwhile, the deep ultraviolet lithography technology may also achieve high-accuracy alignment and multi-layer pattern manufacturing, thereby greatly improving the manufacturing efficiency and quality of microelectronic devices.

However, a focused depth of field of the deep ultraviolet lithography process is generally small. When a substrate has a relatively high step, the exposure may not be performed normally by using the deep ultraviolet lithography process.

The objective of the present disclosure is to provide a deep ultraviolet lithography method, a lithography pattern and a semiconductor structure, so as to provide a technical solution that the exposure may still be performed normally by using a deep ultraviolet lithography process when a substrate has a relatively high step.

On this basis, the embodiments of the present disclosure provide a deep ultraviolet lithography method, which is applied in a substrate having a step. The deep ultraviolet lithography method includes the following steps S100 to S300.

In S100, when a depth of field of the deep ultraviolet lithography is less than a height of the step of the substrate, a pattern to be photoetched is divided into at least two portions according to a distribution situation of the step, where each of the at least two portions corresponds to an on-step pattern or an off-step pattern of the step.

In practice, the focused depth of field of the deep ultraviolet lithography process is relatively small, which is less than 300 nm. When the substrate has a relatively high step, i.e., when a height of the step of the substrate is greater than the focused depth of field of the deep ultraviolet lithography process, the step may not be exposed normally. On this basis, in the embodiments of the present disclosure, the pattern to be photoetched is divided into at least two portions according to a distribution of the step.

In a specific embodiment, when the depth of field of the deep ultraviolet lithography is less than a step pattern of the substrate, dividing the step pattern into at least two portions includes:
dividing, when the depth of field of the deep ultraviolet lithography is less than the step pattern of the substrate and the pattern to be photoetched includes one step pattern, each step pattern into the on-step pattern and the off-step pattern.

In practice, when the pattern to be photoetched includes one step, the step pattern is divided into the on-step pattern and the off-step pattern. When the pattern to be photoetched includes a plurality of steps, each step pattern is divided into the on-step pattern and the off-step pattern. At this time, the focused depth of field of the deep ultraviolet lithography process may cover a height of the on-step pattern or a height of the off-step pattern.

In the embodiments of the present disclosure, when the depth of field of the deep ultraviolet lithography is less than the height of the step of the substrate, before the pattern to be photoetched is divided into at least two portions according to a distribution of the step, the deep ultraviolet lithography method further includes: coating an antireflection layer on the substrate by using a glue spraying method.

It should be understood that the antireflection layer is used to reduce the reflection of the substrate and improve the lithography resolution. When the lithography resolution reaches 130 nm or less, it is desired to provide the bottom antireflection layer on the substrate. At present, a spin coating method is mostly used to form the antireflection layer on the substrate. However, the bottom antireflection coating is very thin, which will lead to a poor spin coating effect in the spin coating process, thus affecting the exposure effect.

On this basis, in the present disclosure, the glue spraying method is used to coat the antireflection film on the substrate, so as to avoid the poor spin coating in the spin coating process.

In the embodiments of the present disclosure, a thickness of the antireflection layer is less than 60 nm. For example, the thickness of the antireflection layer is 55 nm or 50 nm.

In S200, the at least two portions of the pattern to be photoetched are corresponded onto at least two masks respectively.

The at least two portions of the pattern to be photoetched, which are obtained according to the distribution situation of the step, are corresponded onto at least two masks respectively. That is, each mask corresponds to a corresponding on-step pattern or off-step pattern.

In a specific embodiment, the on-step pattern is corresponded onto a first mask, and the off-step pattern is corresponded onto a second mask.

In S300, the exposed at least two masks are baked and developed simultaneously after the at least two masks are exposed sequentially.

As the depth of field of the deep ultraviolet lithography is less than the height of the step of the substrate, the at least two masks are exposed sequentially. Specifically, the first mask is exposed first, and the on-step pattern is selected as a focus plane in the exposure process; after the exposure for the first mask is ended, the first mask is not developed, the second mask is exposed, a focal length offset is set, and the off-step pattern is set as the focus plane; after the exposure for the second mask is ended, the first mask and the second mask are baked and developed together, thereby obtaining a deep ultraviolet lithography pattern.

In a specific embodiment, the simultaneously baking and developing the exposed at least two masks after the at least two masks are exposed sequentially includes:
exposing the first mask first, and then exposing the second mask; and
simultaneously baking and developing the exposed first mask and the exposed second mask.

Based on the above description, in the deep ultraviolet lithography method provided by the embodiments of the present disclosure, a pattern to be photoetched is divided into at least two portions according to a distribution of the step; the at least two portions of the pattern to be photoetched are corresponded onto at least two masks respectively; and after the at least two masks are exposed sequentially, the exposed at least two masks are baked and developed simultaneously. On this basis, in the embodiments of the present disclosure, a step pattern corresponding to a substrate having a step may be photoetched, so as to obtain a corresponding lithography pattern. In the embodiments of the present disclosure, since the step pattern is divided into at least two portions, where each of the at least two portions corresponds to an on-step pattern or an off-step pattern, a depth of field of the deep ultraviolet lithography is greater than a height corresponding to each portion. Therefore, in the present disclosure, the exposure may be performed normally by using the deep ultraviolet lithography process, so as to solve the problem in the related art that the exposure may not be performed normally by using the deep ultraviolet lithography process when a substrate has a relatively high step.

In a second aspect, the embodiments of the present disclosure further provide a lithography pattern. The lithography pattern is prepared by using the ultraviolet lithography method.

On this basis, the lithography pattern provided by the embodiments of the present disclosure is prepared by the ultraviolet lithography method provided by the first aspect. Therefore, the accuracy of the obtained lithography pattern may be guaranteed.

In a third aspect, the embodiments of the present disclosure further provide a semiconductor structure. The semiconductor structure includes a substrate prepared by using the lithography pattern.

It should be understood that as the accuracy of the lithography pattern in the second aspect is guaranteed, the shape of the structure of the substrate prepared by using the lithography pattern is also guaranteed, thereby ensuring the functionality of the substrate and the semiconductor structure.

Compared with the related art, the beneficial effects of the second aspect and the third aspect of the present disclosure are the same as those of the deep ultraviolet lithography method in the above technical solution, which will not be repeated here.

Although the present disclosure are described herein in combination with various embodiments, in the process of implementing the present disclosure protected, those skilled in the art may understand and achieve other variations of the embodiments of the present disclosure by viewing the drawing, the disclosed contents and the appended claims. In the claims, the word “comprising” does not exclude other constituent portions or steps, and “a” or “an” does not exclude plural cases. A single processor or other unit may achieve several functions listed in the claims. Certain measures are recited in mutually different dependent claims, but this does not mean that these measures may not be combined to produce good results.

Although the present disclosure is described in combination with specific features and embodiments thereof, it is obvious that various modifications and combinations may be made without departing from the spirit and scope of the present disclosure. Accordingly, the present specification and drawing are only exemplary illustrations of the present disclosure as defined by the appended claims, and are deemed to have covered any and all modifications, variations, combinations or equivalents within the scope of the present disclosure. Obviously, those skilled in the art may make various modifications and variations to the present disclosure without departing from the spirit and scope of the present disclosure. In this way, if these modifications and variations of the present disclosure are within the scope of the claims of the present disclosure and the technical equivalents thereof, it is also intended that the present disclosure includes these modifications and variations.

What is claimed is:

1. A deep ultraviolet lithography method, applied in a substrate having a step, comprising:
dividing, when a depth of field of the deep ultraviolet lithography is less than a height of the step of the substrate, a pattern to be photoetched into at least two portions according to a distribution situation of the step, wherein each of the at least two portions corresponds to an on-step pattern or an off-step pattern of the step;
corresponding the at least two portions of the pattern to be photoetched onto at least two masks respectively; and
simultaneously baking and developing the exposed at least two masks after the at least two masks are exposed sequentially.

2. The deep ultraviolet lithography method according to claim 1, further comprising:
coating an antireflection layer on the substrate by using a glue spraying method.

3. The deep ultraviolet lithography method according to claim 2, wherein a thickness of the antireflection layer is less than 60 nm.

4. The deep ultraviolet lithography method according to claim 1, wherein when the depth of field of the deep ultraviolet lithography is less than the height of the step of the substrate and the pattern to be photoetched comprises a step pattern corresponding to one step, the step pattern corresponding to the step is divided into the on-step pattern and the off-step pattern.

5. The deep ultraviolet lithography method according to claim 4, wherein the corresponding the at least two portions of the pattern to be photoetched onto at least two masks respectively comprises:
corresponding the on-step pattern onto a first mask, and corresponding the off-step pattern onto a second mask.

6. The deep ultraviolet lithography method according to claim 5, wherein the simultaneously baking and developing the exposed at least two masks after the at least two masks are exposed sequentially comprises:
exposing the first mask first, and then exposing the second mask; and
simultaneously baking and developing the exposed first mask and the exposed second mask.

7. The deep ultraviolet lithography method according to claim 1, wherein the height of the step in the substrate is greater than or equal to 500 nm.

8. A lithography pattern, wherein the lithography pattern is prepared by the deep ultraviolet lithography method of claim 1.

9. A semiconductor structure, comprising a substrate prepared by using the lithography pattern of claim 8.
